(19) United States
(12) Patent Application Publication
(10) Pub. No.: US 2006/0141725 A1
(43) Pub. Date: Jun. 29, 2006

(54) Method of manufacturing flash memory device

(75) Inventors: Seung Cheol Lee, Kyeongki-do (KR); Sang Wook Park, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-shi (KR)

(21) Appl. No.: 11/129,776

(22) Filed: May 16, 2005

(30) Foreign Application Priority Data
Dec. 28, 2004 (KR) 2004-114142

(51) Int. Cl. H01L 21/336

(52) U.S. Cl. 438/301; 438/303; 438/595

(57) ABSTRACT

A method of manufacturing a flash memory device wherein before an insulating film spacer of a contact region is removed after a gate line and source/drain are formed, a high quality buffer oxide film formed between the gate line and the insulating film spacer is made dense by means of an annealing process. Abnormal oxidization is thus prevented from occurring due to an exposed metal layer in a gate when the insulating film spacer is removed as at least part of the buffer oxide remains after the spacer is removed.

### BACKGROUND

1. Technical Field

A method of manufacturing a flash memory device is disclosed which prevents abnormal oxidation of a metal layer in a gate line.

2. Disclosure of the Related Art

A memory cell array of a NAND flash memory device has a string-like structure. The string-like structure includes a drain select transistor connected to a bit line, a source select transistor connected to a common source, and a plurality of memory cells connected between the drain select transistor and the source select transistor in a serial manner. An insulating film spacer is formed on the sidewalls of a gate line of the select transistor and the memory cells.

After source/drain are formed through impurity ion implant, a contact plug has to be formed on a common source and a drain. In order to secure the contact margin, the insulating film spacer adjacent to the contact region is removed. After a buffer oxide film and a buffer nitride film are sequentially formed in order to form a self-aligned contact (hereinafter, referred to as “SAC”), an annealing process for activating an impurity implanted into the source/drain is performed.

In the above, the insulating film spacer is removed by wet etch using H₃PO₄ for about 20 minutes. In this case, the upper portion of the insulating film spacer is wider than the lower portion of the spacer due to manufacturing process characteristics. For this reason, as an upper portion of the insulating film spacer is removed first, the buffer oxide film is exposed. The buffer oxide film has the etch selectivity different from that of the insulating film spacer comprised of a nitride film, and thus has a significant low etch rate. While the insulating film spacer is removed, however, the buffer oxide film is etched, and the metal layer (for example, a tungsten layer) on the gate line is thus exposed.

As a result, in a subsequent SAC process, while a buffer oxide film is formed, abnormal oxidization can be generated in the metal layer, and a lifting phenomenon can occur in the metal layer. This may result in a failure of the device.

FIG. 1 is a photograph showing a lifting phenomenon generated by an abnormal oxidization phenomenon. As shown in FIG. 1, a lifting of the metal layer occurs at a portion where abnormal oxidization occurred. This makes the pattern collapse, and neighboring gate lines came into electrical contact with each other, thus causing a short or failure to occur.

### SUMMARY OF THE DISCLOSURE

Accordingly, in view of the above problems, a method of manufacturing a flash memory device is disclosed, wherein the film quality of the buffer oxide film formed between the gate line and the insulating film spacer is made more dense by means of an annealing process before the insulating film spacer of the contact region is removed and after the gate line and source/drain are formed. As a result, abnormal oxidization is prevented from occurring due to an exposed metal layer on the gate when the insulating film spacer is removed, thereby improving the reliability of the manufacturing process.

In an embodiment, a disclosed method of manufacturing a flash memory device comprises: forming a gate line on a semiconductor substrate; sequentially forming a buffer oxide film and a nitride film on the entire structure including the gate line; etching the nitride film by means of a blanket etch process, thereby forming an insulating film spacer; forming impurity regions in the semiconductor substrate by using the gate line and the insulating film spacer as an ion implant mask; performing an annealing process in order to make the buffer oxide film dense; removing the insulating film spacer; and performing a self-aligned contact process.

The disclosed method can further comprise, before the buffer oxide film is formed, forming low-concentration impurity regions in the semiconductor substrate by means of an ion implant process using the gate line as an ion implant mask.

The insulating film spacer can be removed by means of a wet etch process using phosphoric acid. In this case, the wet etch process can include removing the insulating film spacer with consideration to the etch rate and thickness of the buffer oxide film, but removing the spacer only to the extent that the buffer oxide film remains. For example, the wet etch process can be performed for 5 to 25 minutes.

Furthermore, the buffer oxide film can remain at a thickness in the range of 50 to 150 Å after the insulating film spacer is removed.

### BRIEF DESCRIPTION OF THE DRAWINGS

FIG. 1 is a photograph showing a lifting of metal layers caused by abnormal oxidization; and

FIGS. 2a to 2f are cross-sectional views explaining a disclosed method of manufacturing a flash memory device.

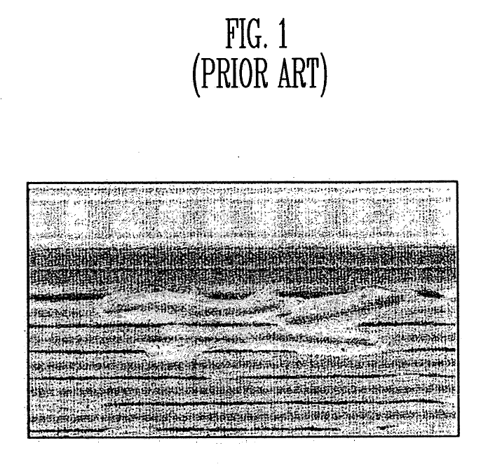

### DETAILED DESCRIPTION OF THE PRESENTLY PREFERRED EMBODIMENTS

The scope of this disclosure is not limited by the preferred embodiments described herein.

Meanwhile, in case where it is described that one film is “on” the other film or a semiconductor substrate, the one film may directly contact the other film or the semiconductor substrate. Or, a third film may be disposed between the one film and the other film or the semiconductor substrate. Furthermore, in the drawing, the thickness and size of each layer are exaggerated for convenience of explanation and clarity. Like reference numerals are used to identify the same or similar parts.

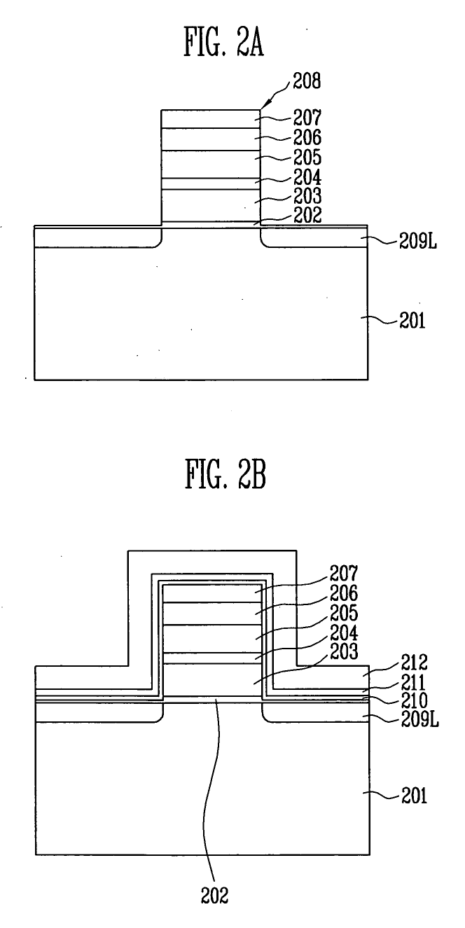

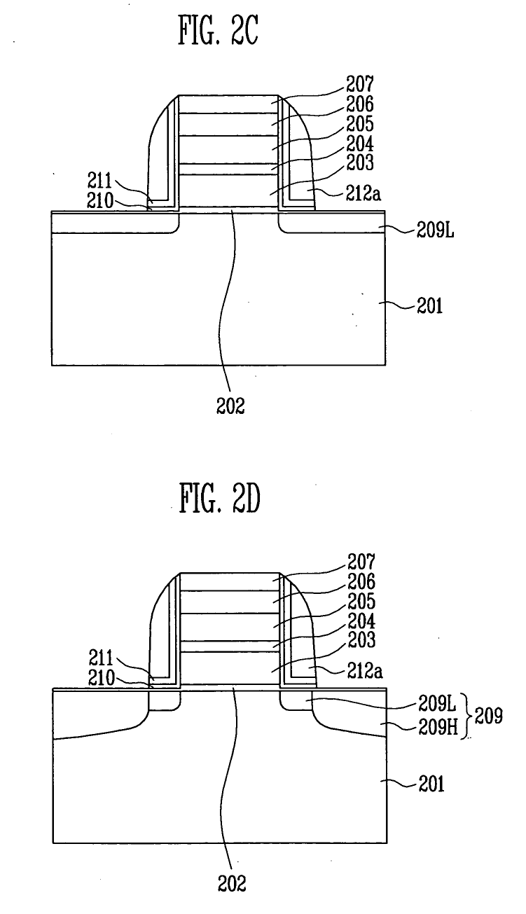

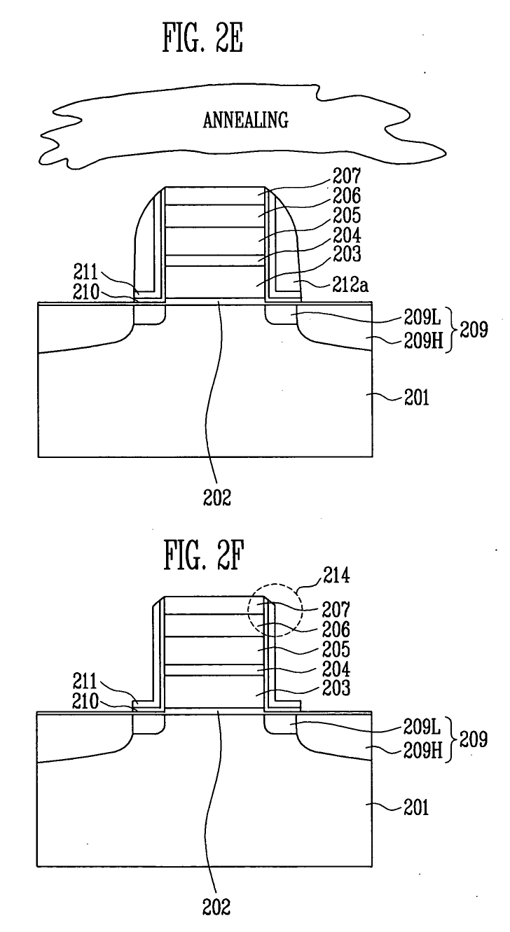

FIGS. 2a to 2f are cross-sectional views for explaining one disclosed method of manufacturing a flash memory device. Referring first to FIG. 2a, a gate line 208 is formed on a semiconductor substrate 201. The gate line 208 can become a gate line of a memory cell or a gate line of a select transistor. In FIG. 2a, the gate line of the select transistor is shown. In this case, the gate line 208 is formed to be twice as narrow as a thickness of an insulating film spacer that is typically formed.

Meanwhile, the gate line 208 can have a stack structure of a tunnel oxide film 202, a floating gate 203, a dielectric film 204, a control gate 205, a metal layer 206 and a hard mask 207 in the same manner as the gate line of the memory cell. In this case, in a subsequent process, an additional process for electrically connecting the floating gate 203 and the control gate 205 of the select transistor is implemented.

Meanwhile, the dielectric film may not be formed in the select transistor region, but the floating gate 203 and the control gate 205 can be electrically connected.

After the gate line 208 is formed, low-concentration impurity regions 209L are formed in the semiconductor substrate 201 between the gate lines 208 by means of an ion implant process. In this case, upon formation of the gate line 208, the tunnel oxide film 202 of the lowest layer remains on the semiconductor substrate 201. This can be used as a screen oxide film in an ion implant process in order to prevent damage to the surface of the semiconductor substrate 201 due to the ion implantation.

Referring next to FIG. 2b, a sealing nitride film 210, a buffer oxide film 211 and a nitride film 212 are sequentially formed on the entire structure including the gate line 208. In this case, the sealing nitride film 210 can be formed to a thickness in the range of 50 to 100 Å, the buffer oxide film 211 can be formed to a thickness in the range of 150 to 300 Å, and the nitride film 212 can be formed to a thickness in the range of 500 to 800 Å. Meanwhile, the buffer oxide film 211 is preferably formed using LP-TEOS.

Referring to FIG. 2c, the nitride film 212, the buffer oxide film 211 and the sealing nitride film 210 are sequentially etched by means of a blanket etch process, thereby forming an insulating film spacer 212a. In this case, the tunnel oxide film 202 remains on the semiconductor substrate 201 at a predetermined thickness in order to prevent generation of etch damage to the surface of the semiconductor substrate 201. For example, the tunnel oxide film 202 can remain in the thickness ranging from 50 to 150 Å.

Referring to FIG. 2d, high-concentration impurity regions 209H are formed in the semiconductor substrate 201 by means of an ion implant process using the insulating film spacer 212a and the gate line 208 as an ion implant mask. A junction region 209 having a LDD structure is thereby formed. In this case, the junction region formed between the source select lines becomes a common source connected to the ground terminal, and the junction region formed between the drain select lines becomes a drain.

Referring to FIG. 2e, in the prior art, the insulating film spacer 212a is first removed. After the buffer oxide film and the nitride film are deposited in order to implement a SAC process, the annealing process for activating the impurity implanted into the junction region 209 is performed. However, before the insulating film spacer 212a is removed, the annealing process is performed. This annealing process is performed under nitrogen atmosphere at a temperature in the range of 700 to 1000° C. for a time period in the range of 10 to 30 minutes.

This annealing process allows an impurity implanted into the junction region 213 to be activated and damages generating due to ion implantation to be compensated for. It also makes the buffer oxide film 211 dense. The reason why the annealing process is first performed is for making the buffer oxide film 211 dense before the insulating film spacer 212a is etched.

Referring to FIG. 2f, the insulating film spacer (212a in FIG. 2e) is removed. This allows a process margin of a process for forming the contact plug to be secured between the gate lines 208, and it also makes a distance between the gate lines 208 narrow as much as a thickness of the removed insulating film spacer (212a of FIG. 2e). Therefore, the degree of integration can be improved.

In this case, the insulating film spacer (212a of FIG. 2e) can be removed using phosphoric acid (H₃PO₄). A wet etch process using phosphoric acid is preferably performed to completely remove the insulating film spacer in consideration of an etch rate and a thickness of the buffer oxide film 211, but is performed only for a time of the degree that the buffer oxide film 211 can remain. For example, the wet etch process can be performed for a time period in the range of 5 to 25 minutes.

In the case where the annealing process is not performed but the wet etch process using phosphoric acid is performed, the etch rate of the buffer oxide film 211 is approximately 8 to 15 Å/min. In the case where the annealing process is first performed as shown in FIG. 2e and the wet etch process using phosphoric acid is then performed, however, the etch rate of the buffer oxide film 211 is lowered to about 2 to 2.5 Å/min.

Therefore, only when annealing is first performed and the insulating film spacer is then removed although the insulating film spacer of the same thickness is etched, the buffer oxide film 211 can remain to prevent exposure of the metal layer 206. The buffer oxide film 211 can also prevent the lifting phenomenon from occurring due to abnormal oxidization generating in the metal layer 206.

Meanwhile, the buffer oxide film 211 can remain intact, and then used in a subsequent SAC process. If a buffer oxide film 211 of a good film quality is required in a subsequent SAC process, however, the buffer oxide film 211 can be removed.

Though not shown in the drawings, a new buffer oxide film and a nitride film for a SAC process are sequentially formed on the entire structure including the gate line 208. Thereafter, an interlayer insulating film is formed on the entire surface, a contact hole is formed on the junction region 209, and a contact plug and a metal line are then formed in a sequential manner, by means of a typical SAC process.

As described above, according to the disclosed method of manufacturing a flash memory device, before an insulating film spacer of a contact region is removed after a gate line and source/drain are formed, a high quality buffer oxide film is formed between the gate line and the insulating film spacer and is made dense by means of an annealing process. Abnormal oxidization of the metal layer is thus prevented from occurring when the insulating film spacer is removed. Accordingly, the disclosed method improves reliability of the flash memory device manufacturing process.

Although the foregoing description has been made with reference to the preferred embodiments, it is to be understood that changes and modifications may be made by those of ordinary skill in the art without departing from the spirit and scope of this disclosure and the appended claims.

What is claimed is:

1. A method of manufacturing a flash memory device, comprising:
forming a gate line on a semiconductor substrate;
sequentially forming a buffer oxide film and a nitride film on the gate line;
etching the nitride film by means of a blanket etch process, thereby forming an insulating film spacer;
forming impurity regions in the semiconductor substrate by using the gate line and the insulating film spacer as an ion implant mask;
performing an annealing process to densify the buffer oxide film;
removing the insulating film spacer; and
performing a self-aligned contact process.

2. The method as claimed in claim 1, further comprising, before the buffer oxide film is formed, forming low-concentration impurity regions in the semiconductor substrate by means of an ion implant process using the gate line as an ion implant mask.

3. The method as claimed in claim 1, wherein the insulating film spacer is removed by means of a wet etch process using phosphoric acid.

4. The method as claimed in claim 3, wherein the wet etch process includes removing the insulating film spacer without removing the buffer oxide film.

5. The method as claimed in claim 3, wherein the wet etch process is performed for a time period ranging from 5 to 25 minutes.

6. The method as claimed in claim 3, wherein the buffer oxide film remains at a thickness in a range from 50 to 150 Å after the insulating film spacer is removed.

7. A method of manufacturing a flash memory device, comprising:
forming a gate line on a semiconductor substrate;
sequentially forming a buffer oxide film and a nitride film on the gate line;
etching the nitride film by means of a blanket etch process, form an insulating film spacer from a remaining portion of the nitride film;
forming impurity regions in the semiconductor substrate by using the gate line and the insulating film spacer as an ion implant mask;
performing an annealing process to densify the buffer oxide film;
removing the insulating film spacer without removing the buffer oxide film.

8. The method as claimed in claim 7, further comprising, before the buffer oxide film is formed, forming low-concentration impurity regions in the semiconductor substrate by means of an ion implant process using the gate line as an ion implant mask.

9. The method as claimed in claim 7, wherein the insulating film spacer is removed by means of a wet etch process using phosphoric acid.

10. The method as claimed in claim 9, wherein the wet etch process includes removing the insulating film spacer without removing the buffer oxide film by considering etch rates of the insulating film spacer and buffer oxide films and timing the wet etch process so at least a portion of the buffer oxide film remains.

11. The method as claimed in claim 10, wherein the wet etch process is performed for a time period ranging from 5 to 25 minutes.

12. The method as claimed in claim 10, wherein the buffer oxide film remains at a thickness in a range from 50 to 150 Å after the insulating film spacer is removed.

13. A method of manufacturing a flash memory device, comprising:
forming a gate line on a semiconductor substrate;
sequentially forming a buffer oxide film and a nitride film over the gate line;
etching the nitride film by means of a blanket etch process, thereby forming an insulating film spacer on top of the buffer oxide film;
forming impurity regions in the semiconductor substrate by using the gate line and the insulating film spacer as an ion implant mask;
performing an annealing process to densify the buffer oxide film;
removing the insulating film spacer without removing all of the buffer oxide film.

14. The method as claimed in claim 13, further comprising, before the buffer oxide film is formed, forming low-concentration impurity regions in the semiconductor substrate by means of an ion implant process using the gate line as an ion implant mask.

15. The method as claimed in claim 13, wherein the insulating film spacer is removed by means of a wet etch process using phosphoric acid.

16. The method as claimed in claim 15, wherein the wet etch process includes completely removing the insulating film spacer without removing the buffer oxide film by limiting a time period for the wet etch process.

17. The method as claimed in claim 16, wherein the wet etch process is performed for a time period ranging from 5 to 25 minutes.

18. The method as claimed in claim 17, wherein the buffer oxide film remains at a thickness in a range from 50 to 150 Å after the insulating film spacer is removed.
